(19) United States
(12) Patent Application Publication
(10) Pub. No.: US 2008/0271994 A1
(43) Pub. Date: Nov. 6, 2008

(54) Method and Apparatus for Using an Electric Field for Controlling of the Crystallizing Material or Materials

(76) Inventor: Mika Tapio Reijonen, Helsinki (FI)

Correspondence Address: BAY AREA INTELLECTUAL PROPERTY GROUP, LLC, PO BOX 210459, SAN FRANCISCO, CA, 94121-0459, US

(21) Appl. No.: 11/997,556

(22) PCT Filed: Jan. 31, 2006
(86) PCT No.: PCT/FI2006/000267

§ 371 Date: Feb. 1, 2008

(30) Foreign Application Priority Data
Aug. 10, 2005 (FI) 20050812

(51) Int. Cl. C25C 3/20; C30B 30/02

(52) U.S. Cl. 204/230.2; 205/687

(57) ABSTRACT

The system consists of two electrodes (1, 4), at least of dielectric layers (2, 3) in one of which (3) is crystallizing material or materials with a possible dielectric solvent, melt or combinations thereof, a voltage supply (5) and a closed circuit. In the invention it is used a dielectric polarization with a new method and an apparatus for the control of the crystallising of materials.

### CROSS-REFERENCE TO RELATED APPLICATIONS

The present Utility patent application is the National Phase filing under 35 U.S.C. 371 of the International Application No PCT/FI2006/000267 filed on Jul. 31, 2006.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection. The copyright owner has no objection to the facsimile reproduction by anyone of the patent document or patent disclosure as it appears in the Patent and Trademark Office, patent file or records, but otherwise reserves all copyright rights whatsoever.

### FIELD OF THE INVENTION

According to a method and an apparatus it is influenced on crystal structures and crystal forms of materials, and these are influenced of the properties of the mixture which contains crystals. Different crystal structures and crystal appearances have big significances on the properties of materials. Especially in the pharmaceutical, polymer, metal and electronic industry the control of the crystallizing is outstandingly important. Lawrence X. Yu, Robert A. Lionberger, Andre S. Rawa, Rosario D'Costa, Huiquan Wu and Ajaz S. Hussai: Applications of Process Analytical Technology to Crystallization Processes (gotten from http://www.fda.gov/cder/OPS/patcrystalSub.pdf8 Aug. 2005). In the first sentence of this abstract it is told about the importance of the crystallizing in the pharmaceutical industry, where this is the most critical and least understood matters.

### BACKGROUND OF THE INVENTION

All or nearly all molecules can be polarized even if they did not have a permanent dipole, because the electric field induces dipole moment to them. By the effect of the electric field, the dielectric polarization happens which means the orientating of the charges in them. If a material is like an electrode as in the patent publication WO2004081264 made by the inventor, the electric double layer is forming which take place with the interface between an electrode and an electrolyte such as for an example it is shown in the statement 2199 of VTT on page 81 (gotten from http://www.vtt.fi/inf/pdf/tiedotteet/2003/T2199.pdf8 Aug. 2005). The difference from the before patented method is the fact that now crystallizing material does not operate as a second electrode, in other words it is not so conducting. Now presented invention is based on a dielectric polarization.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1. A system of one insulating layer. Electrodes (1 and 4), dielectric layer (2), dielectric layer (3) which contains the crystallizing material, adjustable voltage supply and direction of the voltage in the closed circuit. Electrodes and dielectric layers can be changed and the temperature and a mixture can be regulated and for example the change of the voltage, the consumption of the current and spectrofotometric analysis can be made (5), such as Raman measurements perform on line from the point 3.

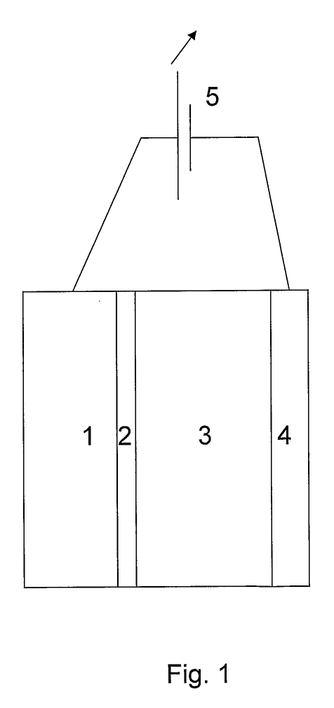

FIG. 2. A system of two insulating layers. Electrodes (1 and 4), dielectric layers (2), dielectric layer (3) which contains the crystallizing material, adjustable voltage supply and direction of the voltage in the closed circuit. Electrodes and dielectric layers can be changed f and the temperature and a mixture can be regulated and for example the change of the voltage, the consumption of the current and spectrofotometric analysis can be made (5), such as Raman measurements perform on line from the point 3.

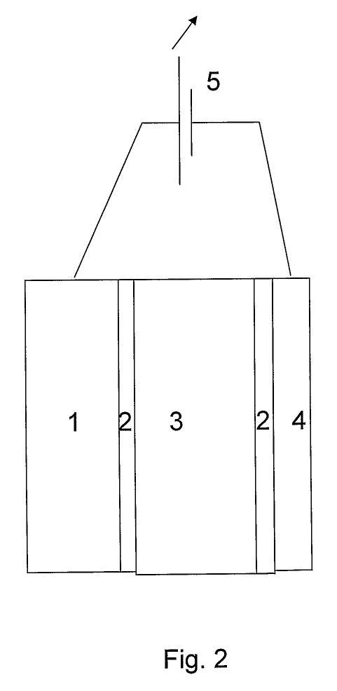

Unless otherwise indicated illustrations in the figures are not necessarily drawn to scale.

### SUMMARY OF THE INVENTION

The present invention contains a method and an apparatus for controlling crystallization by dielectric polarization using one or more insulating layers and dielectric medium containing crystallization substances. Advantageously, the system enables to use the high electric field without electrolysis and in the large area without an electric double layer formed and so the electric field reduced in some molecular layers.

### DETAILED DESCRIPTION OF THE PREFERRED EMBODIMENTS

The present invention is best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

The present invention will now be described in detail with reference to embodiments thereof as illustrated in the accompanying drawings.

In accordance with the method of the invention it is possible to use also large electric force, which otherwise would lead to the powerful electrolysis, neither as another electrode in being, whereby resulting polarization range is not long. The crystallizing material is being as other electrode in the patent publication of the same inventor. The crystallizing material is as an insulator, i.e. dielectric material, whose conductivity compared with an electrode is small. With the help of the electric effect, the desired effect of the forming of crystals is obtained. Polarization has been utilised also in other methods but similar as here it is not before presented. The electrochemical reactions, in other words the electrode reactions take place in a phase boundary of electrode-electrolyte.

In the U.S. Pat. No. 6,426,406 a material is crystallized via polarization such as in the invention but in the US patent it takes place with the help of the laser. The method has been described in the Nature journal D. W. Oxtoby: Crystals in a flash. Nature 420, 277-278, 2002. According to this presented effect, one does not take place directly and the force of the electric field cannot be easily regulated and it is not possible to polarize a wide area.

There is a method where crystallizing material is between two electrodes, where researchers used air columns over both the electrodes. (M. Taleb, C. Didierjean, C. Jelsch, J. P. Mangeot, B. Capelle and A. Aubry: Crystallization of proteins under an external electric field. Journal of Crystal Growth. 200, 575-582, 1999). By this method, they got crystallizing only a drop, i.e. 10 microlitres.

There is a method where dielectric material, cocoa butter crystallizes between two electrodes. Here different polymorphic forms, in other words the structures of crystals are obtained from the medium itself without other insulating layer. Y. Y. Yan and R. S. Neve. The effect of electric fields is polymorphism crystallisation. In book Heat Transfer Science

and Technology 2000, edited by Bu-Xuan Wang, Higher Education Press, Beijing, China 745-750, 2000.

In the publication K V. Saban, J. Thomas, P A. Varughese and G. Varghese: Thermodynamics of crystal nucleation in an external electric field. Cryst. Res. Technol. 37, 11, 1188-1199, 2002 was studied in an aqueous solution crystallizing from the effect of the external electric field where the phase transformation is depending on ratio of the dielectric constants of the latter and former phases to refer the study of Liun and Gun “Their work shows that the external electric field may increase or decrease the free energy required for the phase transformation depending on the ratio of the dielectric constants of the latter and former phases”. They came to a conclusion: “The application of electric field is an efficient tool to get very fine control over the nucleation rate of crystals in saturated solutions”.

Currently in the publication Jiancheng Tang, Shandong Li, Xingyu Mao and Youwei Du: Effect of electric field is the crystallization process of amorphous Fe86Zr7B6Cu1 alloy, J. Phys. D: Appl. Phys. 38, 729-732, 2005 made a conclusion: “An electric field has a great influence is the crystallization process of amorphous alloys”. Also the need for the monitoring of conditions can be seen in this publication so that the desired crystallizing product will be obtained.

The electric double layer will form in the fluid, if fluid is an electrolyte, in other words as an electrode, and the area that has been polarized in this way is small, but by using a dielectric system instead of this electrolyte solution according to the invention the whole dielectric is obtained advantageously to the polarization event of material with the voltage, which is big enough. It is possible to use also a small current with comparing to the voltage, if it is needed for the desired position of the molecules in the forming in the crystallizing.

Basic knowledge of dielectric polarization is clear for example (gotten from http://www.stuk.fi/julkaisut/stuk-a/stuk-a198.pdf on pages 86-918 8 Aug. 2005).

From the point of the view of electric static materials are conductors or insulators. The conductor contains free charges, which are able to move in material.

On the contrary in the insulator, all charges are bound to the components of material, i.e. to the molecules. In the insulator, the charges cannot move but they can cluster again by the action of the electric field (a power field). In that case material will be polarize, in other words material undergoes a dielectric polarization.

In the insulator, in other words on dielectric material, there are at all no free charges so from the point of view of the electrostatics but all the charges are bound to the molecules of material. When the dielectric material is brought to an electric field or an external electric field is directed to it, the field will cause to each charge the power which tries to move the charge either in the direction of the field (the positive charges) or in the opposite direction (the negative charges), columbic forces. In the molecules, differential, atomar transition of charges takes place as its consequence in other words they the forming again, so that the positive charge concentration will form in the other end of the molecule and to other negative one. This phenomenon is called a dielectric polarization, and it is particularly the property of the insulators. It is said that in that case the insulator is polarized.

The limit exists for the voltage in which case the insulator does not hold out and the breakdown happens. This is advantageous in the invention to use high voltages, and thus it can used for the polarization of molecules and it can happen in the environment which these have strongly bound. Also the leakage current can exist when a small current goes a system. This can also be utilised in the invention without the strong electrolysis taking place even though the voltage is high.

The method which is in accordance with the invention can be adjusted easily with the help of the voltage (in the picture 1 the point 5). The method can be influenced by a solvent or solvents, pH, the choice of a drug or drugs or excipients.

The scalability and the capacity can be easily directly automated, and the method can be carried out in a batch or a continuous process. The method of duplicating for example pile or cylinder like is easy. The crystallizing method fulfils demands from GMP (good manufacturing practice) and using easily sterile because of its simplicity. The method can also be easily combined with analysis devices, such with on line Raman spectroscopy.

Usually organic materials are insulators, so the suitability of the method is extremely large. For example, the table sugar aqueous solution does not conduct electricity. Using dielectric materials there are big possibilities, because even though crystallising material would conduct electricity, it can be put for example to olive oil or linseed oil, and it can be crystallized in it as a mixture and, if needed, remove crystals from oil by filtering or with other method. It is also possible that, when a mixture crystallizes, for example adding leading materials, and materials get the desired properties.

In order to find suitable conditions, the monitoring will be important, furthermore, when there are different dielectric values and on the molecules there are different dipole moments which can change when the shape of the molecule changes, the monitoring tools are needed to crystallizing like process analytical technologies (PAT) to guarantee efficient working. It is advantageous that in the invention the use of these monitoring tools is easy.

There is a wide suitability with the method, because every material can be polarized and many materials are dielectric or they can be put to a dielectric mixture. The supersaturation state is required for the crystallizing and it will be reached by cooling, by evaporating or these combinations, with the pressure or with the help of other materials, and these are well known methods. The material, materials or mixed crystals which have crystallized, are removed from the mixture by filtering or in other way, if necessary. In the method, crystallization conditions can be advantageously changed like with the temperature, and the progress of the crystallizing will be measured.

### EXAMPLES

### Example 1

The dielectric layer (2) is 50 micrometers thick polystyrene layer. As a solution of a dielectric layer (3) is ethanol and the crystallizing material is ibuprofen. According to the present knowledge, the crystallizing has two steps, the birth of a seed crystal, i.e. nucleation and the growth of the crystal. According to the present knowledge, during the nucleation the crystal information is created. So in the method is the worth to be at the beginning of the situation, when nucleation is not to yet started. Thus for example with the decreasing of the temperature or with the other solvent help will be first obtained a supersaturated state, after then forming of the seed crystal and growth of the crystal. At this stage, the desired electric field will be used during the crystallizing according to the invention, and possibly in addition to nucleation, expanding for whole crystal growing. With the adjusting (5) of the voltage the force of the electric field is regulated. The electrodes (1 and 4) are made of stainless steel. The crystallization container has been made from polytetrafluorethene.

### Example 2

Here it is used comparable equipment like in example 1 but there are as a dielectric layer (3) with a mixed of molten polymer and conducting materials. When a molten polymer crystallizes, a conducting material will organize to a polymer.

### Example 3

Here it is used comparable equipment like in example 1 but there are as a dielectric layer (3) heated gel solution and drug for example ibuprofen or ketoprofen or their mixture. When temperature falls the drug contained gel is formed during the electric field affects on polymerization and crystallization. This has an effect both for the forming of polymer chains and on the crystallizing of the drug.

### Example 4

Here it is used comparable equipment like in example 1 but there are as a dielectric layer (3) heated gel solution and drug for example ibuprofen or ketoprofen or their mixture. When the temperature decreases, the drug contained gel is formed during the electric field affects on polymerization and crystallization. This has an effect both for the forming of polymer chains and on the crystallizing of the drug. The invention can be used for the control of the crystallizing of the only polymer or a mixture of polymer.

### Example 5

Here it is used comparable equipment like in example 1 but there are as a dielectric layer (3) is air or gas for example of nitrogen or the mixture of gases. A material crystallizes through saturated gas.

### Example 6

Here it is used comparable equipment like in example 1, and it has equipped with several monitoring tools for both the input and the output measurements A voltage is measured on line and it is done with the oscilloscope, and the online Raman spectroscopy is used and the x-ray diffraction methods are in use. The adjustment of temperature and the mixture are automated and all parts of the system are under the computer control and extremely much information gathers between milliseconds and the process is quickly automatically to change, and it is possible to make programmed procedures.

For those skilled in the arts are clear that the invention is not limited to the presented details, such for example as in the choice of the electrodes and of dielectric materials or a voltage or current magnitude, known crystallization methods for the combined to this invention flow, for example flow through method in continuous process.

What is claimed is:

1. A method using polarization for the controlling of the crystallizing of material or materials comprising of
two electrodes (1 and 4)
at least two dielectric layers (2 and 3) in one of which (3) is crystallizing material or materials with a possible dielectric solvent, melt or combinations thereof
voltage supply (5) and closed circuit
crystallization container.

2. The method according to the claim 1 a crystallizing material in a dielectric layer is a fluid, gas or melt.

3. The method according to the claim 1 a crystallizing material can be a mixture with a dielectric material.

4. The method according to the claim 1 in dielectric layer 3 there can be inorganic, organic materials or combinations thereof, a solvent, melt or mixture fluid or solid or gaseous of their mixture, typically clean water, 100% ethanol or their mixture in which case they serve mainly as a dielectric material. Other examples as the components of the mixture are other alcohols, such as propanol, ketone such as acetone, glycerol, pentane, hexane, carbon tetrachloride, chloroform, benzene, toluene, petrol, turpentine, fats, such as olive oil, rapeseed oil, cocoa butter, linseed oil or biopolymer or mixture of biopolymer.

5. The method according to the claim 1 in dielectric there are containing the non crystallizing layer material consisted typically of polyethene, polytetrafluorethene, polycarbonate, polyvinylchloride, polyester, polymethylmethacrylate, polystyrene, polyamide, polyformaldehyde, polysulfone, phenolic plastic, aminoplast, quartz, ceramic material, rubber, bakelite, lustre, porcelain, glue, varnish, paint, a product of petrochemistry, an oxide of metal or glass or combinations thereof.

6. The method according to the claim 1 dielectric layer containing the non crystallizing material is thin typically in 10-100 micrometers thick, if necessary, the crystallization width can be adjusted, typically, in a 0.5-10 cm area.

7. The method according to the claim 1 the voltage can be regulated by using typically high voltages and if needed a small current.

8. The method according to the claim 1 the voltage (5) can be regulated in a 0-10000 kV area, and if necessary, the direction of the voltage can be changed.

9. The method according to the claim 1 the system can be typically duplicated pile, roll, radius or cylinder like.

10. The apparatus as claimed in the claim 1, wherein the width of a dielectric layer (3) can be changed, the adjustable voltage supply functions in a 0-100000 kV area, a dielectric layer (3) containing a crystallizing material is 0.5-10 cm wide. The apparatus contains of metal electrodes (1 and 4) and a dielectric layer (2).
